(19) United States
(12) Patent Application Publication
(10) Pub. No.: US 2011/0089542 A1
(43) Pub. Date: Apr. 21, 2011

(54) Area reduction for electrical diode chips

(76) Inventor: Jeng-Jye Shau, Palo Alto, CA (US)

(21) Appl. No.: 12/592,489

(22) Filed: Nov. 25, 2009

Related U.S. Application Data
(63) Continuation-in-part of application No. 12/589,163, filed on Oct. 19, 2009.

(51) Int. Cl. H01L 23/552; H01L 21/56; H01L 23/60

(52) U.S. Cl. 257/660; 438/124; 257/E21.502; 257/E23.114

(57) ABSTRACT

Using electrical printing technologies to form package level conductor leads for electrical diode circuit, the preferred embodiments of the present invention significantly reduces the areas of surface mount electrical diodes or ESD circuits. Besides area reduction, these methods also provide significant cost saving and reduction in parasitic impedance. Additional cost reduction can be achieved by using none-crystalline semiconductor electrical diodes.

This application is a continuation-in-part application of previous patent application with a Ser. No. 12/589,163, with a title “Area Reduction for Electrical Diode Chips”, and filed by the applicant of this invention on Oct. 19, 2009.

### BACKGROUND OF THE INVENTION

The present invention relates to electrical circuits comprising electrical diodes, and more particularly to structures and methods for reducing the areas of surface mount electrical diode chips.

Semiconductor electrical diodes are commonly used for rectifying circuits and for electrostatic discharge (ESD) protections. By definition, an electrical diode is a two-terminal rectifying semiconductor device used for rectifying or for ESD protection. Examples of electrical diodes include P-N junction electrical diodes, Schottky diodes, and breakdown diodes such as transient-voltage-suppression (TVS) electrical diodes, avalanche diodes or Zener diodes. Optical devices such as solar cells, optical or infrared sensors, and light emitting diodes (LED) are not considered as electrical diodes because their major function are optical instead of electrical. FIG. 1(a) shows a schematic symbol of a P-N junction electrical diode or a Schottky diode; FIG. 1(b) shows a schematic symbol for a breakdown diode. One of the methods to make a break down diode is to increase the doping density of junction diodes. Another common method is to connect the base and emitter of a bipolar junction transistor (BJ) as shown in FIG. 1(f). Sometimes a resistor (Rbe) is placed between the base and emitter of the bipolar transistor (BJ) as shown in FIG. 1(f). Due to transistor snap back mechanisms, the devices in FIGS. 1(f, g) can function as equivalent circuits of breakdown diodes. The same symbol in FIG. 1(b) is used to represent TVS diodes, avalanche diodes, Zener diodes, bipolar transistors with shorted emitter/base, or other types of diodes that are designed to break down safely at pre-defined ranges of reverse biased voltages; and they are all called “breakdown diodes” in this patent application. FIG. 1(c) shows an exemplary electrical diode circuit that is a rectifier using 4 electrical diodes.

Electrostatic discharge (ESD) is the sudden and momentary electric current that flows between two objects at different electrical potentials caused by direct contact or induced by an electrostatic field. ESD is a serious issue in solid state electronics, such as integrated circuits (IC). State of the art integrated circuits comprise high performance components with dimensions measured in nanometers (nm). Such high sensitive circuit components are not designed to survive ESD attacks. They are typically isolated from external connections to avoid ESD damage. IC input and/or output (I/O) circuits that are exposed to external environments are typically thick gate, long channel, low performance devices manufactured by processes different than those for high performance core circuits. In addition, on-chip ESD protection circuits such as snap-back transistors or electrical diodes are used to protect I/O circuits from ESD attacks. Circuits designed to survive ESD attacks and circuits designed for performance have conflicting requirements. The super-fine precision of advanced IC technology makes ESD protection more difficult. For example, the nano-meter contacts and vias used in advanced IC technologies often become the weak spots during ESD attacks. To build ESD tolerant components, additional manufacture steps (ESD implant, silicide block, thick gate transistors, . . . ) are required to support ESD tolerant circuits. Therefore, on-chip ESD protection circuits occupy significant areas, require additional manufacture steps, and cause performance problems. It is therefore highly desirable to provide ESD protection chips external to integrated circuit chips in order to replace or to simplify on-chip ESD protection circuits.

By definition, a “chip” is a packaged semiconductor device that is ready for board level assembly. Therefore, a chip comprises semiconductor devices as well as conductor leads and protection materials packaged around the semiconductor devices. A die without packaging is therefore not a chip. By definition, “external electrostatic discharge (ESD) protection circuits” are ESD protection circuits that are produced to protect circuits that are external to the chip that comprises the ESD protection circuits.

Traditional ESD protection devices include snap-back transistors and electrical diodes. Electrical diodes used for ESD protection devices are used as examples of preferred embodiments in this patent application. External ESD protection chips have been developed using electrical diodes as the major protection components. For example, Texas Instruments (TI) TPD4E001 is an external ESD protection chip that can protect 4 I/O signals. FIG. 1(d) shows a schematic diagram for TI TPD4E001. This device has 4 I/O pins (IO1-IO4), one power supply pin (VDD) and one ground pin (VSS). The first I/O pin (IO1) is connected to two electrical diodes (DD1, DS1); electrical diode DD1 is connected to power supply pin (VDD); and electrical diode DS1 is connected to the ground pin (VSS), as shown in FIG. 1(d). Similarly, the other three I/O pins (IO2-IO4) are connected to electrical diodes (DD2-DD4) that are connected to the power supply pin (VDD) and electrical diodes (DS2-DD4) that are connected to the ground pin (VSS). A breakdown diode (ZD1) is connected between VDD and VSS, as shown in FIG. 1(d). At normal operation conditions, all the electrical diodes (DD1-DD4, DS1-DS4, ZD1) are under reverse biased conditions with high impedances. If a negative charge is placed on IO1 during ESD attack, DS1 is forward biased and provides a safe path to discharge to ground. If a positive charge is placed on IO1 during ESD attack, DD1 is forward biased and ZD1 breakdown to provide safe paths to discharge to VDD and/or ground. The protection mechanisms are similar for other I/O pins (IO2-IO4).

ESD protection electrical diodes also can be integrated with other types of circuits. For example, Texas Instruments SLLS876 comprises 6 channels of ESD protection circuits integrated with electromagnetic interference (EMI) filters in one chip. FIG. 1(e) shows a schematic diagram for one channel of TI SLLS876 EMI/ESD protection chip. The channel input (Ch_In) of the device is connected to a breakdown diode (ZD41), a capacitor (C41) and a resistor (R41), while the channel output (Ch_Out) is connected to another breakdown diode (ZD42), another capacitor (C42), and the other terminal of R41; the other terminals of ZD41, C41, C42, ZD42 are connected to ground, as shown in FIG. 1(e). The resistor (R41) and the two capacitors (C41, C42) form an EMI filter. “Pi” filter is used in this example while “T” filter is also commonly used for this application. Sometimes, the parasitic capacitors of the diodes (ZD41, ZD42) are used to serve the functions of the capacitors (C41, C42) of the EMI filters. The breakdown diodes (ZD41, ZD42) provide ESD protections to circuits connected to Ch_In and Ch_Out. If a negative charge is placed on Ch_In during ESD attack, ZD41 is forward biased and it provides a safe path to discharge to ground. If a positive charge is placed on Chin during ESD attack, ZD41 provides a safe path to discharge to ground using the breakdown mechanism of the breakdown diode. If a negative charge is placed on Ch_Out during an ESD attack, ZD42 is forward biased and it provides a safe path to discharge to ground. If a positive charge is placed on Ch_Out during an ESD attack, ZD42 provides a safe path to discharge to ground using the breakdown mechanism of the breakdown diode.

These and other external ESD protection devices are typically manufactured by IC technologies that are optimized for ESD protection circuits. FIGS. 2(a-e) are simplified symbolic diagrams illustrating exemplary manufacture steps of prior art ESD protection chips. FIG. 2(a) is a simplified view of a single-crystal semiconductor substrate (209) that comprises a plurality of dice (200). A die (200) is a repeating unit on a substrate that can be sliced to support a chip. A common example for single-crystal semiconductor substrate is a silicon wafer. FIG. 2(b) shows a magnified picture of the marked area of the wafer in FIG. 2(a). In this example, the die (200) in the semiconductor substrate (209) is separated by scribe lanes (208) from other dice; and bonding pads (212) on the surface of the die provide openings for external connections. After the electrical diodes and other electrical components have been manufactured on the semiconductor substrate (209), the die (200) in the wafer is sliced along the scribe lanes (208) to serve as an individual device. FIG. 2(c) is a simplified symbolic diagram for one sliced die (200). In this example, the die (200) comprises 4 channels (210) of ESD/EMI circuits with components shown by the schematic in FIG. 1(e). A channel (210) in the die (200) comprises two bonding pads (212), two breakdown diodes (201), two capacitors (202), and one resistor (203) as illustrated in FIG. 2(c). Sometimes the capacitors (202) can be replaced by parasitic capacitors without using separated capacitor devices. For clarity, in FIG. 2(c) and in other figures, simplified symbols are used to represent structures that can be very complex. The structures of semiconductor components (222) are not discussed in detail. The bonding pads (212) provide openings on the semiconductor substrate for external connections to the circuit components (222) on the semiconductor substrate. Two ground and/or power pads (216) provide ground and/or power connections.

External ESD protection circuits are typically manufactured by IC manufacture processes on single crystal semiconductor substrates. The technologies used to manufacture external ESD circuits are optimized for ESD protections. Therefore, external ESD protection chips are typically more effective against ESD attacks than typical on-chip ESD protections. On-chip ESD protection typically can pass human body model ESD tests at 2000 volts, while external ESD protection chips typically can pass the test at higher than 16000 volts. However, the ESD protection circuit on the semiconductor die (200) in FIG. 2(c) is not ready for application; it needs conductor leads to allow board level electrical connections to the electrical components on the die. Prior art ESD protection circuits are typically placed in integrated circuit packages to provide conductor leads for external connections. For example, TI SLLS876 is placed inside a “thin dual-in-line flat” (TDFN) package. FIG. 2(d) is the top view illustrating the structures when the die (200) in FIG. 2(c) is placed into an Integrated circuit package (219) to form a chip, and FIG. 2(e) shows the cross-section view of the packaged chip along the marked line in FIG. 2(d). The bonding pad (212) on the die (200) provides openings for external connections to the electrical components (222) on the single crystal semiconductor device. Bonding wires (218) connect the bonding pads (212) to metal traces (215) in the package (219). Such package level metal traces (215) are typically called “lead frames”. The lead frames (215) are connected to external metal pins (214) at the edges of the package as illustrated in FIGS. 2(d, e). Ground connection (216) in this example is connected to a metal pad (216) at the bottom of the TDFN package through another bonding wire (211). Some chips may use pins to support ground connections.

Although prior art ESD protection chips have been proven to be highly effective against ESD attacks, their usage is limited. The most important reason is the area of prior art ESD chips are too large. External ESD protection chips use circuits manufactured on single crystal semiconductor substrates that are placed in IC packages. The sizes of prior art external ESD protection chips are similar to those of IC chips at equivalent I/O counts. For example, TI TPD6F002 uses a package that is 3 mm by 1.35 mm. There is typically not enough room to place such prior art external ESD chips to protect a large number of signals. For this reasons, prior art external ESD protection chips are only used for small number of special signals, such as RF signals, or for special applications. ESD circuits are integrated into chips in order to save circuit board areas for applications such as cellular phones. The capabilities of mobile devices typically are determined by the capability to pack chips into a small space. Therefore, the capability to reduce the areas of external ESD protection chips is typically the most important factor to determine the value of ESD protection chips or diode chips. The electrical industry had invested tremendous efforts trying to reduce the area of ESD chips using various IC packaging technologies. The present invention discloses effective methods and structures to reduce areas of ESD protection chips or electrical diode chips by printing technologies.

Prior art external ESD protection chips use single crystal diode circuits that are placed in IC packages. The costs of prior art external ESD protection chips are therefore similar to those of IC chips at equivalent I/O counts. It is typically more cost effective to use on-chip ESD protections than to use prior art external ESD protection chips. The bonding wires and the lead frames in the integrated circuit packages typically introduce parasitic inductance around 2 nh and parasitic capacitance around 2 pf—values that are large enough to cause problems for high performance signals. It is therefore highly desirable to reduce the costs and the parasitic impedances of external ESD protection chips.

One prior art method to reduce the size and the parasitic impedance of external ESD protection chips is to use ball grid array (BGA) packages. For example, TI places two breakdown diodes into one BGA package that is 1.2 mm by 1.2 mm in area. FIG. 2(f) shows exemplary cross section structures when the die (200) in FIG. 2(c) is placed in a BGA package (240). In this example, the semiconductor die (200) is placed upside down on top of a BGA substrate (242). To reduce parasitic impedance, bumping balls (245), instead of bonding wires, are used to form connections between bonding pads (212) on the die (200) and metal traces (246) on the BGA substrate (242). The metal traces (246) are connected to soldering balls (249) through vias (247) and pads (248) on the BGA substrate (242). BGA packages are typically smaller than TDFN packages, but the cost of BGA packages are typically higher than TDFN packages of the same I/O count. Sometimes bonding wires are used to form connections between the bonding pads (212) and the metal traces (246) at a lower cost but higher parasitic impedances.

The above examples show that formation of conductor leads is the major source of area, cost, and performance problems for prior art external ESD protection chips or electrical diode chips. “Conductor leads” of a chip, defined in this patent application, are the electrical conductors in a packaged chip that provide electrical connections from internal circuits to board level circuitry external to the chip. For the prior art example in FIGS. 2(d, e), a “conductor lead” comprises bonding wire (218), lead frame (215), and package pin (214). For the prior art example in FIG. 2(f), a “conductor lead” comprises a bumping ball (245), metal trace (246), via (247), pad (248), and soldering ball (249). Such complex conductor leads on integrated circuit packages typically result in large size, high cost, and high parasitic impedance. It is therefore desirable to use other methods to provide packaging for ESD protection chips or electrical diode chips.

Technologies similar to the printing technologies used for publication have been developed to manufacture passive electrical circuit components such as resistors, capacitors, or resistor-capacitor (RC) filters. FIGS. 8(a-e) are simplified diagrams illustrating examples of various electrical printing technologies. FIG. 8(a) shows a printing method where a roller (893) with a print pattern (894) rolls over a substrate (891). The substrate can be ceramic, metal, plastic, paper, semiconductor, or many other types of materials. Inks selectively attached on the roller (893) are printed on the substrate with the desired pattern (895) as illustrated on FIG. 8(b). Besides rollers, blocks, plates, films, or other types of printing media also can be used for printing. Besides rolling, printing media can have various motions. For example, print by “stamping” typically means print by linear motions of blocks, plates, or films. Electrical printing technologies are similar in principle to publication printing technologies except that the ink used by electrical printing comprises electrical materials so that dried-ink would function as conductors, insulators, resistors, dielectrics, or semiconductors. Electrical devices can be manufactured at low cost by printing layer(s) of electrical materials with desired patterns.

There are other variations of electrical printing technologies, such as screen printing and inkjet printing. Screen printing is a printing technique that uses a woven mesh to support an ink-blocking stencil. The attached stencil forms open areas of mesh that transfer ink as an image onto a substrate. When screen printing is used to manufacture electrical circuit components, materials with different electrical properties, such as conductors, insulators, resistors, or semiconductors, are mixed with solutions as ink and patterned onto a substrate by screen printing. FIGS. 8(c, d) are simplified symbolic illustrations of screen printing technologies. A stencil (802) with the desired printing pattern (804) is placed on top of a substrate (801) as illustrated in FIG. 8(c). Typical materials for stencils include woven meshes of silk or steel. The substrate can be ceramic, metal, plastic, paper, semiconductor, or many other types of materials. A roller (803) or other mechanism presses ink through the printing pattern (804). After the stencil (802) is removed, a patterned desired material (805) is printed on the substrate (801) as illustrated in FIG. 8(d). Typically, heating and drying processes are applied to solidify the printed materials. The final materials patterned by screen printing or other types of printing processes are typically “dried-ink” that was in liquid or paste form as printed and became solid form after heat treatment or other types of drying processes. Multiple layers of dried-ink materials can be printed on the same substrate using similar processes to form electrical components.

FIG. 8(e) is a simplified diagram illustrating an inkjet printing method. In this example, a printer head (812) injects electrical materials as ink (813) onto a substrate (811) to form a desired pattern (815). The locations and shapes of the printed patterns are controlled using mechanism similar to those in computer inkjet printers.

FIGS. 8(f-h) illustrate a printing method called “dipping”. Most of printing technologies involve application of ink on flat substrates. Dipping is a variation of printing technology that dip printing objects into ink. FIG. 8(f) illustrates the situation when ink lines (831) in liquid or paste form are printed on a flat surface, and a substrate (830) is moved toward the ink lines (831). The substrate (830) is stopped when it is dipped into the ink lines (831), as illustrated in FIG. 8(g). When the substrate (830) is removed from the ink lines (831), ink with desired pattern (833) stick to the edges of the substrate (830) as illustrated in FIG. 8(h). After heat treatments, dried-ink materials in solid form are deposited and patterned on the edges of the substrate (830). The shape of printed structure depends on the ink pattern as well as the shape of the substrate. Sometimes the ink is spread across the whole surface without shape. Sometimes the ink pattern can be very complex. FIGS. 8(f-h) are symbolic diagrams illustrating simplified views of dipping of a single substrate. In practice, a large number of substrates are dipped into ink of different patterns. Dipping is a printing technology that is typically used to build conductor leads at the side wall of chips.

For clarity, simplified symbolic figures are used to describe complex technology, while details such as material processing, temperature control, precision control are not included in our discussions. Printing, by definition, comprises three basic steps: (1) preparing ink that comprises desired electrical material(s) mixed with liquid solution(s) or paste(s); (2) patterning the ink in liquid or paste forms on the surface of desired object; and (3) drying the ink to remove solution in the ink to form desired dried-ink materials as solid electrical materials. Examples of electrical printing technologies include screen printing, inject printing, stamping, flexography, gravure, dipping, or offset printing.

Resistor chips in surface mount package have been manufactured by printing technologies. FIGS. 3(a-f) are simplified illustrations for the manufacturing of surface mount resistor chips using printing technologies. The first step is typically to print patterned conductors (301) on a substrate (300) as illustrated in FIG. 3(a). Alumina is a common substrate material. Silver pastes are common materials used as the ink for conductors. Heat treatments at a temperature and timing profile specified by manufacturers are typically applied after each printing process to transform the conductor inks into dried-ink electrical conductors. The next step is to print resistor films (302) between the conductors (301) as illustrated in FIG. 3(b). Silver and Palladium alloy is an example of the material used for printed resistors. The geometry and the sheet resistance of the resistor films (302) determine the resistance values. After heat treatments, a protective insulator layer (303) is typically printed to cover the resistor layer (302) as illustrated in FIG. 3(c). Epoxy resin is a typical material used for the protective insulator layer. The next step is to print an electrode layer (304) to cover the exposed conductor plates (301) as illustrated in FIG. 3(d). Nickel is a common material for the electrode layer (304). After electrical components have been printed, the substrate (300) is sliced into individual chips (310) as illustrated in FIG. 3(e). In this example, the chip (310) in FIG. 3(e) comprises the circuits in the area marked by dark lines on the substrate (300) in FIG. 3(d). Sometimes, a side wall conductor (305) is printed by stamping or deposited by dipping after slicing. FIG. 3(f) shows simplified cross section structures along the line marked in FIG. 3(e). FIG. 3(g) shows three dimensional external views for printed chips such as the resistor chip in FIG. 3(e). For this example, each resistor chip (310) comprised 8 edge conductor leads (365) to support 4 resistors. An “edge conductor lead”, by definition, is a conductor lead deposited on the surface(s) and extended to the edge(s) of a surface mount package chip. The conductor leads illustrated in FIGS. 3(q-k) and FIGS. 4(g, h) are examples of edge conductor leads. The conductor leads shown in FIG. 2(f) or FIG. 5(c) are not “edge conductor leads” because they are placed in the middle of the chip without extending to the edge(s) of the chip. Using edge conductor leads typically leads to smaller chip sizes and excellent mechanical properties after soldering on printed circuit boards (PCB). The edge conductor leads (365) that provide board level I/O connections to the resistor chip (310) comprise conductors (304, 305, 301) that directly contact electrical components in the chip; no bonding wires, lead frames, or pins are used. The parasitic inductance of such connections is typically much lower than the parasitic inductance of the package connections on Integrated circuit packages. A resistor chip typically has 1 to 8 resistors. FIG. 3(h) shows an exemplary three dimensional view of a two-I/O printed chip such as a resistor chip with one resistor. The size of an 8-I/O chip is roughly 4 times the size of a 2-I/O chip. There are various designs of printed circuit chips. Sometimes, side wall conductors (375) are printed by stamping or deposited by dipping to extend the edge conductor leads, as illustrated by the chips (370, 378) in FIGS. 3(I, j). Sometimes, grooves (385) are added between edge conductor leads, as illustrated by the chip (380) in FIG. 3(k). Sometimes, the side wall conductors are deposited in the grooves instead of between grooves. Chips with similar structures are also used for other electrical components such as resistor-capacitor (RC) filters.

The electrical industry is using a widely accepted naming convention that is related to the dimensions of resistor chips or other printed circuit chips. This naming convention uses two digit numbers related to the length (RL1, RL) of the chip followed by two or three digits related to the width or I/O pitch (RW1, RW) of the chip. For example, if the chip (368) in FIG. 3(h) is a standard “0402” resistor chip, then the length of the chip (RL1) should be about 0.04 inches, while the width of the chip (RW1) should be about 0.02 inches. The thickness (RH1) of the chip is relatively less important so it is typically not specified in the naming convention. For chips with more than two I/O edge conductor leads, the naming of the chips are typically related to the length (RL) between the ends of the opposite pair of edge conductor leads and the pitch between nearby edge conductor leads (RW), as illustrated in FIG. 3(g). For example, if the chip (310) in FIG. 3(g) is a standard 0402 resistor chip, then the length (RL) between the ends of the opposite pair of edge conductor leads should be about 0.04 inches, while the pitch between nearby edge conductor leads (RW) should be about 0.02 inches. The thickness (RH) of the chip is relatively less important so it is not specified in the naming convention. Table 1 lists commonly available resistor chips and their dimensions. For example, if the chip (368) in FIG. 3(h) is a standard “0402” resistor chip, then the length of the chip (RL1) should be about 0.04 inches, while the width of the chip (RW1) should be about 0.02 inches. If the chip (310) in FIG. 3(g) is a standard 0402 resistor chip, then the length (RL) between the ends of opposite pair of edge conductor leads should be about 0.04 inches, while the pitch between nearby edge conductor leads (RW) should be about 0.02 inches. For another example, if the chip (368) in FIG. 3(h) is a standard “0201” resistor chip, then the length of the chip (RL1) should be about 0.024 inches, while the width of the chip (RW1) should be about 0.012 inches. If the chip (310) in FIG. 3(g) is a standard 0201 resistor chip, then the length (RL) between the ends of opposite pair of edge conductor leads should be about 0.024 inches, while the pitch between nearby edge conductor leads (RW) should be about 0.016 inches. For another example, if the chip (368) in FIG. 3(h) is a standard “01005” chip, then the length of the chip (RL1) should be about 0.016 inches, while the width of the chip (RW1) should be about 0.008 inches. This industry naming standard has been widely used to describe the dimensions of not only resistor chips but also other types of printed electrical circuits such as RC components. This patent application will follow this industry standard to describe dimensions of ESD chips or electrical diode chips with printed edge conductor leads.

TABLE 1
standard dimensions of surface mount resistor chips

| | Distance between opposite edge | Width in | Pitch in |
|---|---|---|---|
| Name | conductor leads in inches | inches | inches |
| 0603 | 0.063 | 0.031 | 0.031 |
| 0402 | 0.04 | 0.02 | 0.02 |
| 0201 | 0.024 | 0.012 | 0.016 |
| 01005 | 0.016 | 0.008 | 0.012 |

In the electrical industry, packages shown in the above examples are commonly called “surface mount rectangular passive component” (SMRPC) packages because they are typically used for surface mount passive components such as resistor chips, capacitor chips, or resistor-capacitor (RC) chips. SMRPC packages are typically significantly smaller and cheaper than integrated circuit packages or electrical diode packages of equivalent I/O count. The major reason is that the conductor leads for SMRPC packages are typically edge conductor leads. Printing technologies, such as screen printing, inject printing, stamping, flexography, gravure, dipping, or offset printing, have been applied to print passive electrical components at low costs. The costs of printed circuits are typically significantly lower than the costs of circuits using integrated circuit packages. The areas of printed chips are typically smaller than the areas of packaged IC chips. Printing technologies not only can achieve smaller size and lower cost but also can reduce parasitic inductance. Edge conduct leads of printed circuit chips are typically directly printed on the substrates; there is no need to use lead frames and bonding wires. Therefore, the parasitic inductances of printed edge conductor leads are typically significantly lower than those of integrated circuit packages.

In the art of electrical designs, electrical printing technologies are often called “thick film technologies”, in contrast to “thin film technologies” commonly used for integrated circuits. That is because the thicknesses of printed films are typically thicker than 10 micrometers while the thicknesses of “thin films” commonly used in integrated circuits are typically thinner than 2 micrometers. The resolutions of electrical printing technologies are typically measured in tens of micrometers. Such resolution is certainly not enough to support the manufacture of advanced integrated circuits, but it is enough to pattern conductor leads of external ESD protection chips or rectifying diodes.

### SUMMARY OF THE PREFERRED EMBODIMENTS

The primary objective of our preferred embodiment is, therefore, to reduce the area of ESD protection chips or electrical diode chips. The other objective of our preferred embodiment is to provide cost effective external ESD protection chips or electrical diode chips. The other objective of our preferred embodiment is to reduce the parasitic inductance on the I/O connections of external ESD protection chips or electrical diode chips. These and other objectives are achieved by patterning conductor leads of ESD protection chips or electrical diode chips using dried-ink conductors patterned by printing processes.

While the novel features of the invention are set forth with particularly in the appended claims, our preferred embodiments, both as to organization and content, will be better understood and appreciated, along with other objects and features thereof, from the following detailed description taken in conjunction with the drawing.

### BRIEF DESCRIPTION OF THE DRAWINGS

FIGS. 1(a-g) are schematic diagrams of electrical diodes and ESD protection circuits;

FIGS. 2(a-f) illustrate structures of a prior art ESD protection chip;

FIGS. 3(a-k) are simplified symbolic diagrams illustrating printing processes for making prior art resistor chips;

FIGS. 4(a-i) are simplified symbolic diagrams illustrating printing processes for an exemplary ESD protection chip packaged using resistor chip packaging technologies;

FIGS. 5(a-c) are simplified symbolic diagrams illustrating another exemplary ESD protection chip using solder balls as conductor leads;

FIGS. 6(a-i) are simplified symbolic diagrams illustrating manufacture processes for none-crystalline semiconductor electrical diodes;

FIGS. 7(a-e) are simplified symbolic diagrams illustrating manufacture processes for another type of none-crystalline semiconductor electrical diodes;

FIGS. 8(a-h) are simplified illustrations of examples of electrical printing technologies; and

FIGS. 9(a-d) are cross-section views for none-crystalline electrical diodes printed on circuit boards.

### DETAILED DESCRIPTION OF THE PREFERRED EMBODIMENTS

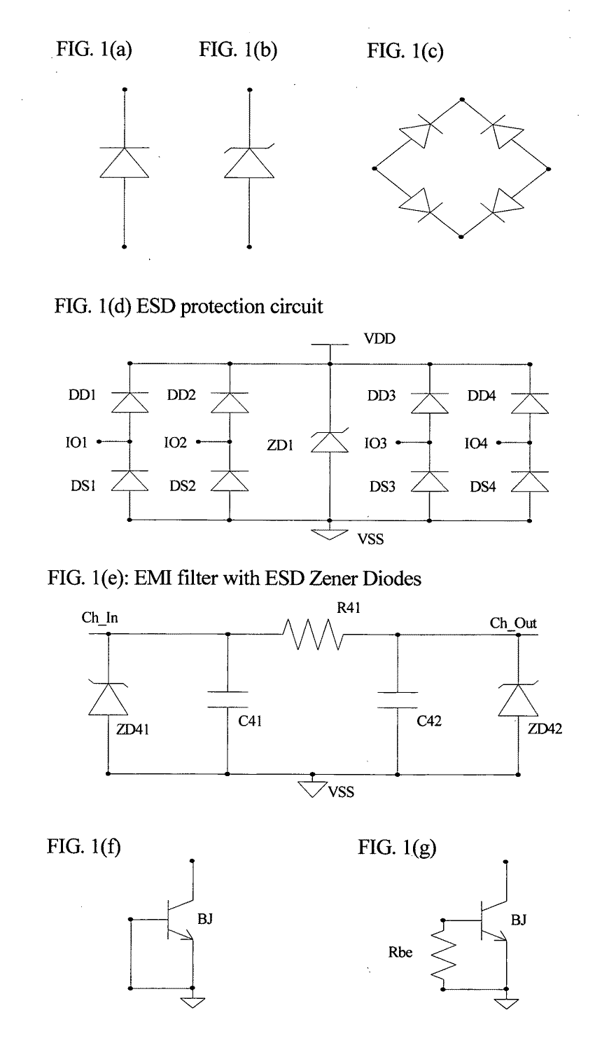

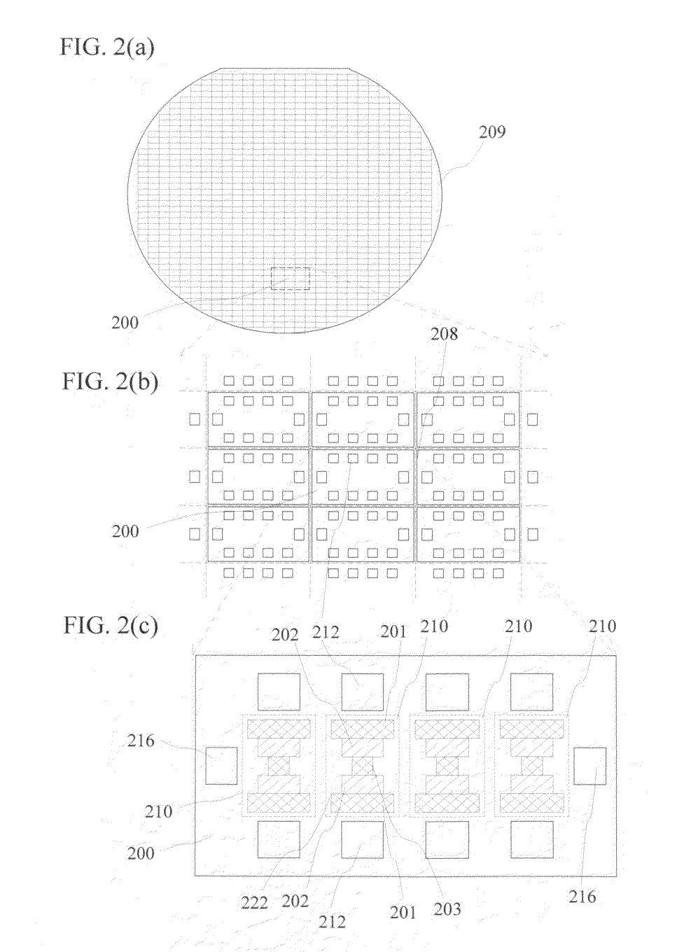

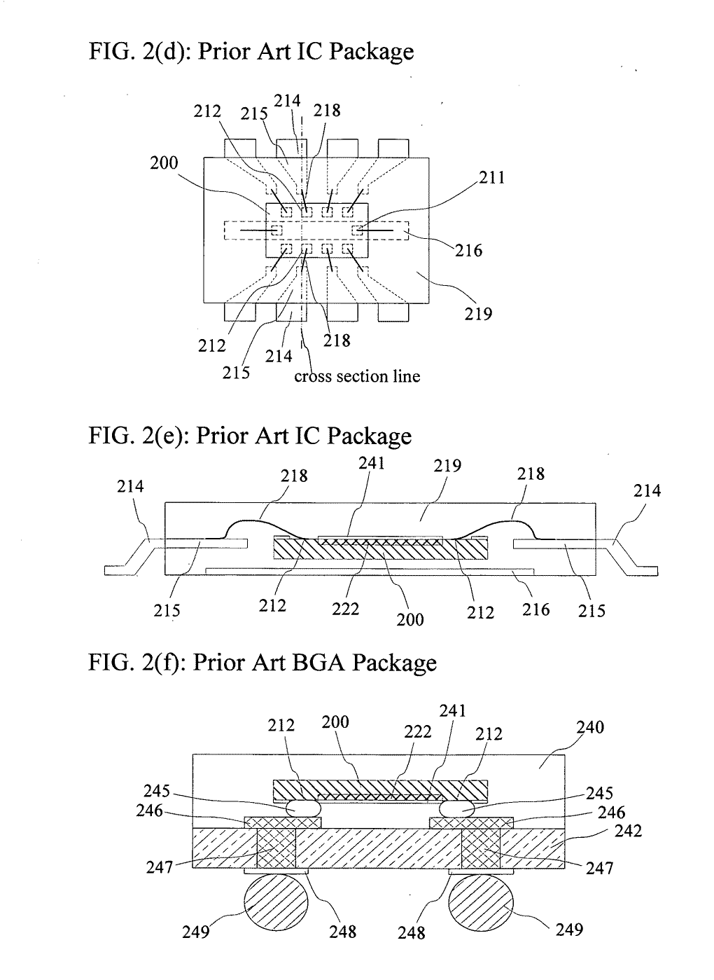

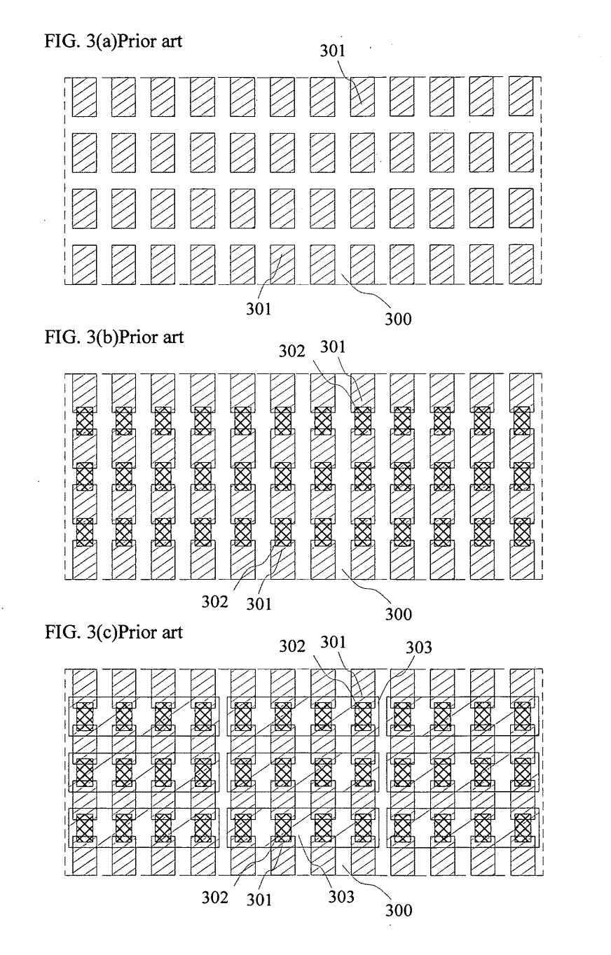

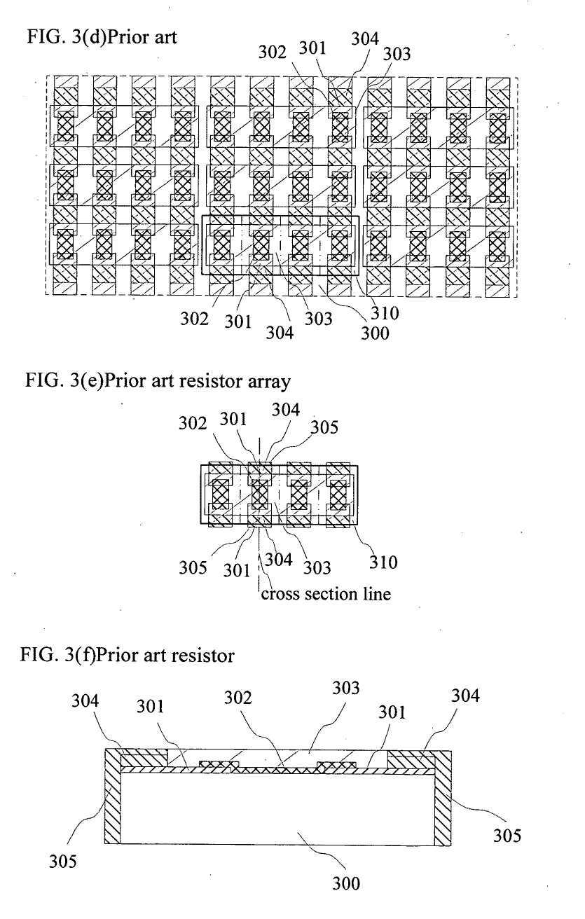

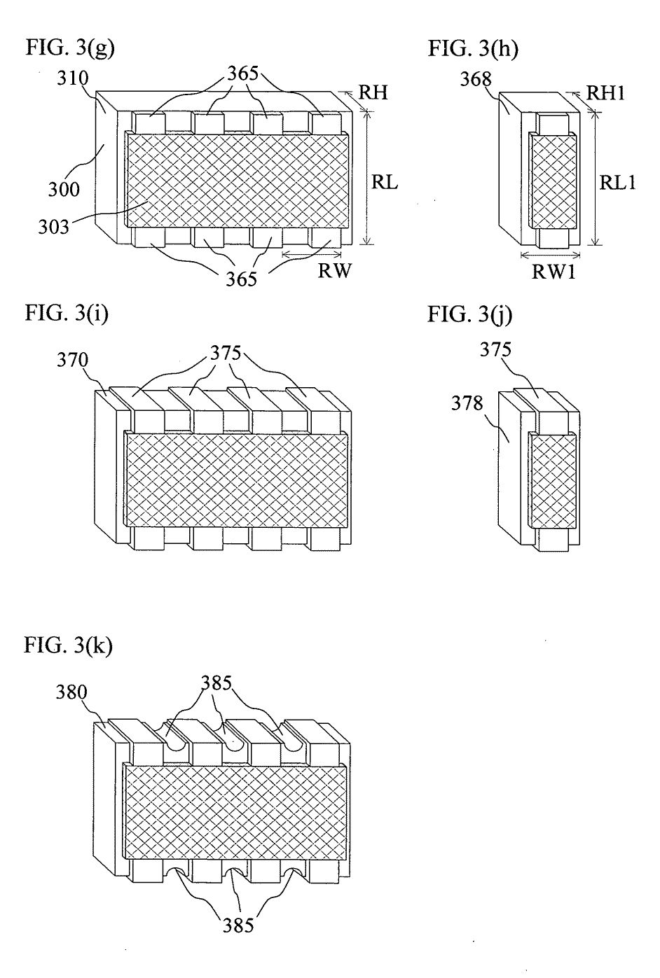

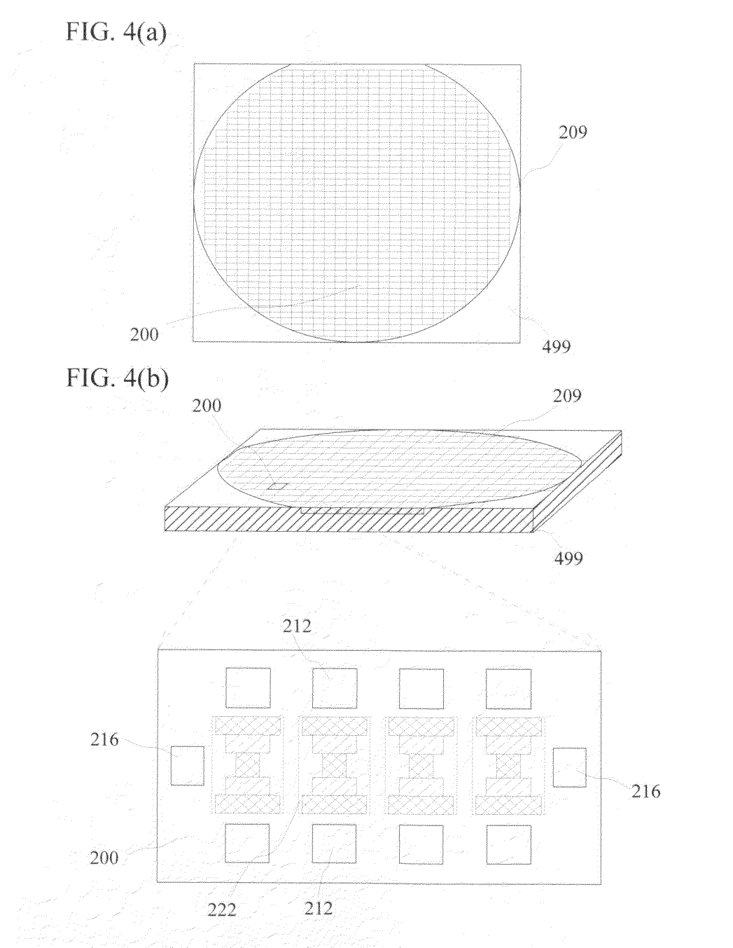

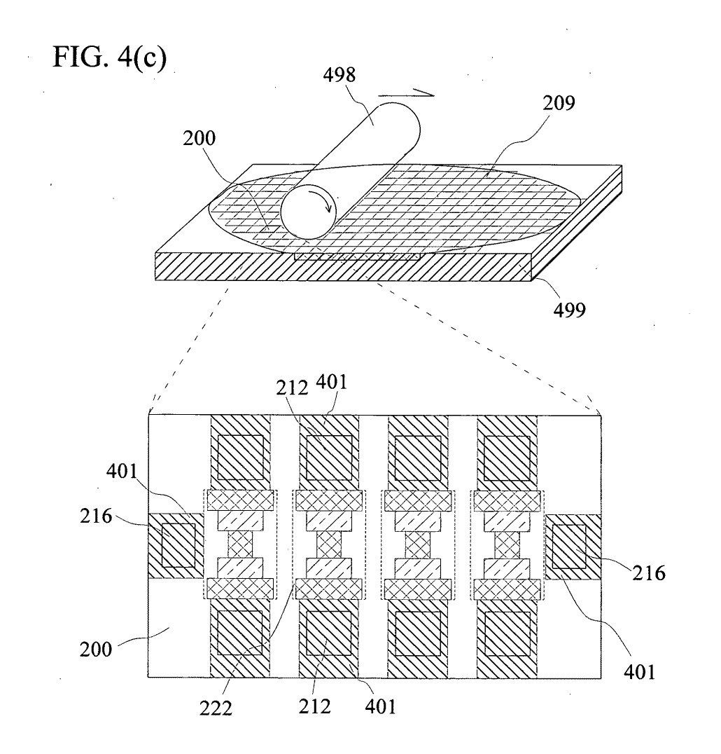

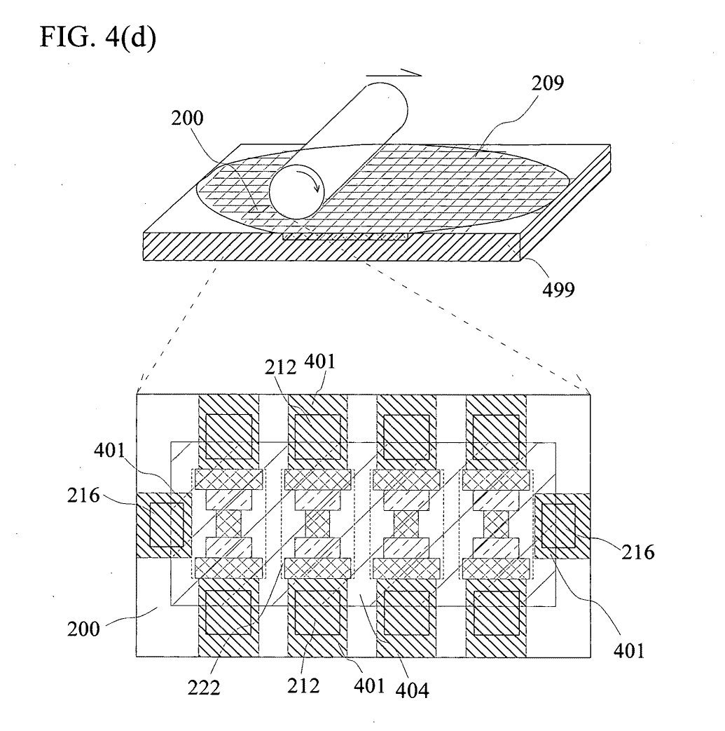

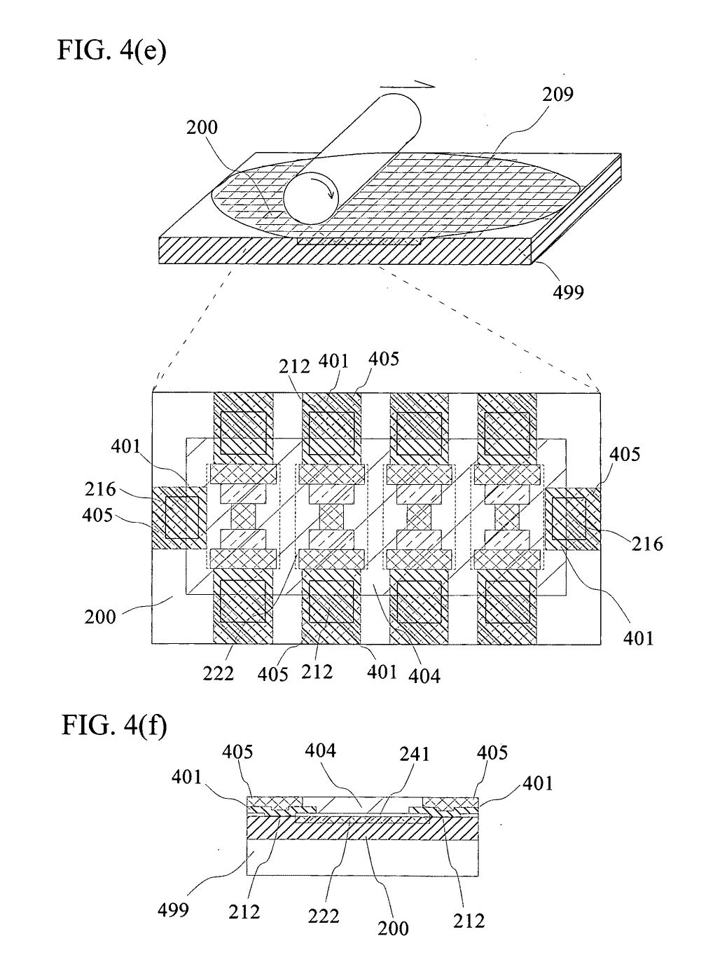

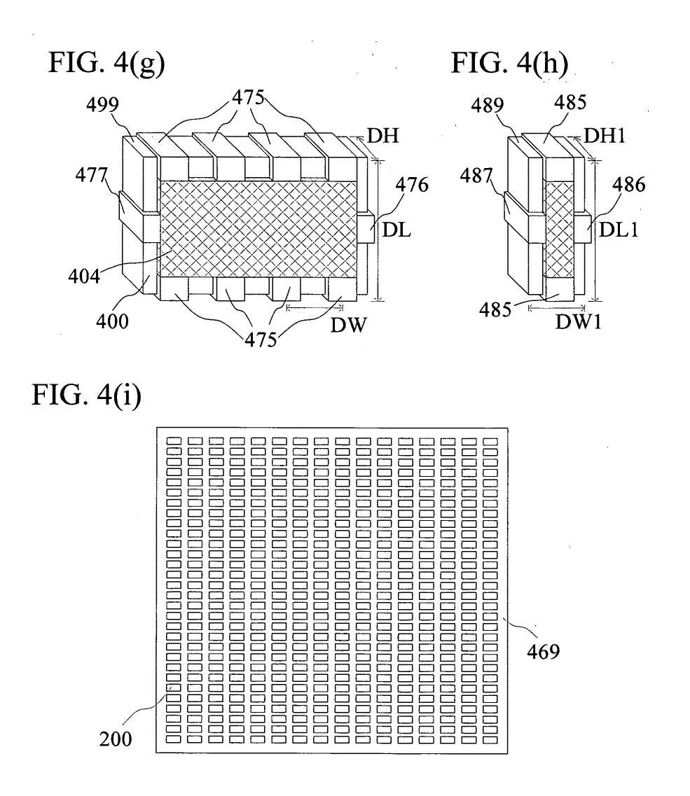

Prior art external ESD protection chips typically comprise single crystal semiconductor substrates placed in Integrated circuit packages. As discussed in previous examples, packaging is typically the major source of area, cost, and performance problems for prior art external ESD protection chips, while area is typically the most important factor determining the value of ESD protection chips. FIGS. 4(a-i) show exemplary processes to reduce the areas of ESD protection chips. In this example, a single crystal semiconductor wafer (209) has been manufactured in similar ways as the example shown in FIG. 2(a). Electrical components such as electrical diodes, resistors, capacitors, and pads have been manufactured on the wafer (209) in similar ways as the examples shown in FIGS. 2(a-c). The single crystal semiconductor wafer (209) is thinned down by back grinding, and molded into a rectangular substrate (499) as shown in FIG. 4(a). The materials of this molded substrate (499) can be epoxy, plastic, glass, metal, ceramic, or other types of materials. This substrate (499) is made to provide the shape and the mechanical strength suitable for printing processes. FIG. 4(b) shows another view of the substrate (499) in FIG. 4(a) and magnified symbolic views of the structures in one die (200) on the substrate (499). In this example, this die (200) has the same structures as the die in FIG. 2(c). In the following steps, printing technologies are used to make electrical connections to the die (200) in similar ways as the resistor printing technologies illustrated in FIGS. 3(a-i). For simplicity, printed structures on one die instead of all the dice on the substrate (209) were shown in the following figures. Printing process is symbolized by a roller (498) pressing on substrate (499), while electrical printing technologies, such as screen printing, inkjet printing, stamping, flexography, gravure, dipping, offset printing, or others, are applicable for this application, so we will not specify a particular printing technology for our examples. Starting from the structures in FIG. 4(b), surface conductors (401) are patterned on the substrate to make electrical connections to the pads (212, 216), as illustrated in FIG. 4(c). These surface conductors (401) can be patterned by IC technology or printing technology. If IC technology is used, aluminum films patterned by lithography are commonly used. If printing technology is used, as illustrated in this example, silver dried-ink formed from silver pastes are common materials used for this application. It is typically desirable to introduce roughness on the semiconductor surface where the printed conductor is applied. Heat treatments at temperature and timing profiles specified by manufacturers are typically applied after each printing process to form dried-ink solid materials. It is certainly possible to use both types of technologies to form the surface conductors (401). After forming the surface conductors (401), a protective insulator layer (404) is printed to provide mechanical cover as illustrated in FIG. 4(d). Epoxy resin is a typical material used for the protective insulator layer (404). After forming the protective insulator layer (404), an electrode layer (405) is printed to cover the exposed conductor layer (401) as illustrated in FIG. 4(e). Dried-ink Nickel alloy is a common material for the electrode layer (405). The substrate (499) is then sliced into individual chips. FIG. 4(f) is a simplified symbolic cross-section view of the structures in FIG. 4(e). FIG. 4(g) shows a three dimensional external view of an ESD/EMI chip (400) using the sliced die in FIG. 4(e). In this example, a dried-ink side wall conductor is deposited on the chip as part of the edge conductor leads (475). Such side wall conductors are typically printed by stamping or formed by dipping. The surface conductors (401), as part of the edge conductor leads (475), provide external electrical connections from edge conductor leads (475) to internal circuits (222) in the chip. The ground and/or power connections are provided by the edge conductor leads (477, 476) at the left and right hand sides of the chip (400) in FIG. 4(g). Electroplating is commonly used to coat additional conductor layer(s) on the conductor leads for better electrical and mechanical properties. In this example, the chip (400) comprised 4 channels of ESD/EMI protection circuits. The external structures of this chip (499) are similar to the chip (370) in FIG. 3(i) except the edge conductor leads (486, 487) at the left hand and right hand sides. It is therefore possible to achieve chip areas about equal to or smaller than resistor chips of equivalent I/O counts. FIG. 4(h) shows one example for a chip (489) that comprises one channel of ESD/EMI protection circuits. This single channel chip (489) comprises edge conductor leads (485) for I/O connections and edge conductor leads (486, 487) for ground and/or power connections for circuits similar to that in FIG. 1(e). The external structures of this chip (489) are similar to the chip in FIG. 3(j) except the edge conductor leads (486, 487) at the left hand and right hand sides of the chip. Besides single channel or 4 channel chips, chips with 2, 6, 8, or other numbers of channels can be manufactured using similar methods.

The ESD/EMI protection chip illustrated in FIGS. 4(e, f, g) can support the same functions as the prior art ESD/EMI protection chip shown in FIGS. 2(d, e). The difference is in packaging—integrated circuit packages are replaced by printed packages with edge conductor leads that comprise dried-ink conductors patterned by printing process(es). In this example, the shapes of the chips (489, 499) are designed to be similar to standard 0402 or 0201, 01005 or other SMRPC chips. Compared to the external structures of the resistor chip in FIG. 3(i), the only differences in external structure of this chip are the extra edge conductor leads (476, 477) at its sides. Other types of electrical diode circuits also can be manufactured in similar processes. For example, the ESD protection circuits in FIG. 1(d) also can be manufactured in similar processes. For the case of ESD protection circuits in FIG. 1(d), each I/O pin requires one conductor lead. Therefore, a chip similar to the chip (499) in FIG. 4(g) can protect 8 ESD I/O signals with two power/ground connections, and a chip similar to the chip (489) in FIG. 4(i) can protect 2 ESD I/O signals. General purpose electrical diodes or breakdown diodes shown in FIG. 1(a, b) also can be manufactured using similar printed conductor leads. For example, chips similar to the chips (368, 378) in FIGS. 3(h, i) can host one electrical diode, and chips similar to the chips (310, 370, 380) in FIGS. 3(g, i. k) can host 4 electrical diodes. The rectifier circuit in FIG. 1(c) also can be structured using similar edge conductor leads. The shape of rectifier chips can be similar to those in FIGS. 3(g-k) or FIG. 4(g-h). For example, two rectifiers can be placed in a chip similar to the chips (310, 370, 380) in FIGS. 3(g, I, k), and one rectifier can be placed in a chip similar to the chip (489) in FIG. 4(h).

The cost for a printed package is typically significantly lower than the cost for an IC package. However, the pitch between edge conductor leads is typically larger than the pitch between IC pads. In order to support edge conductor leads, the IC pad pitch may be larger than typical pad pitch, which may result in a larger IC area. Additional structures may be needed to adapt for the needs of printing technologies. The overall cost is determined by the competing factors of package cost and die cost. For ESD protection chips or electrical diode chips, using printed packaging technologies usually reduce overall cost.

As illustrated by the above examples, forming edge conductor leads using printed dried-ink conductors allows the possibilities to make the areas of electrical diode chips (489, 499) to be substantially the same as or smaller than standard 0402 or 0201 or 01005 resistor chips of equivalent I/O counts. Areas smaller than the smallest resistor chips are also achievable because the dimensions of diodes can be smaller than the dimensions of resistors. It is desirable to make the dimensions of electrical diode chips (489, 499), such as the example in FIGS. 4(g, h), similar to the dimensions of 0402 or 0201, 01005, or other types of surface mount resistor chips. It is also desirable to make the footprints of the electrical diode chips (489, 499) compatible with the footprints of standard 0402, 0201, 01005, or other standard surface mount resistor chips. Making dimensions similar to standard resistor chips allow the flexibilities of using existing machines to assembly electrical diode chips of the present invention in similar ways as resistor chips, providing significant operational cost savings. By definition in this patent application, for a standard “0402” chip, the distance between opposite ends of edge conductor leads for I/O signals is 0.04 inches, and the pitch between nearby edge conductor leads for I/O signals is 0.02 inches. Therefore, “A chip with area substantially the same as or smaller than the area of standard 0402 surface mount resistor chips of equivalent I/O count” means the chip area is approximately equal to or smaller than [(0.04 inches times 0.02 inches) times ((number of I/O edge conductor leads on the chip) divided by 2)], that is, roughly 0.0004 inch² times the number of I/O edge conductor leads on the surface mount package chip. By definition, for a standard “0201” chip, the distance between opposite ends of edge conductor leads for I/O signals is 0.024 inches, and the pitch between nearby edge conductor leads for I/O signals is 0.016 inches. Therefore, “A chip with area substantially the same as or smaller than the area of standard 0201 surface mount resistor chips of equivalent I/O count” means the chip area is approximately equal to or smaller than [(0.024 inches times 0.016 inches) times ((number of I/O edge conductor leads on the chip) divided by 2)], that is, roughly 0.0002 inch² times the number of I/O edge conductor leads on the surface mount package chip. By definition, for a standard “01005” chip, the distance between opposite ends of edge conductor leads for I/O signals is 0.016 inches, and the pitch between nearby edge conductor leads for I/O signals is 0.012 inches. Therefore, “A chip with area substantially the same as or smaller than the area of standard 01005 surface mount resistor chips of equivalent I/O count” means the chip area is approximately equal to or smaller than [(0.016 inches times 0.012 inches) times ((number of I/O edge conductor leads on the chip) divided by 2)], that is, roughly 0.0001 inch² times the number of I/O edge conductor leads on the surface mount package chip. The “area” referred to in the above definitions is the area of the soldering surface on a surface mount chip that is designed to contact printed circuit boards. Ground and/or power conductor leads are not counted as I/O conductor leads. Because the edge conductor leads (475) are connected to the pads through wide conductors (403, 405, 401), the parasitic inductances of such packages are typically much lower than those of Integrated Circuit packages.

While specific embodiments of the invention have been illustrated and described herein, it is realized that other modifications and changes will occur to those skilled in the art. For example, side wall conductors may or may not be used as part of the edge conductor leads after die slicing. The shape of the molding substrate in FIG. 4(a) does not have to be rectangle. It is also possible to print directly on the semiconductor wafer without using a molding substrate. Besides conductors, we also can print resistors, capacitors, or other electrical components on the substrate. Electrical components can be placed on both sides of the substrate instead of one side of the substrate. For the example in FIG. 4(a), the semiconductor wafer was molded before die slicing. FIG. 4(i) shows an example where dice (200) on the semiconductor wafer (209) have been sliced before being put into a substrate (469) for printing conductor leads. This substrate (496) can be processed in similar ways as the above example. These and other variations will be obvious upon disclosure of the present patent application. It is to be understood that there are many other possible modifications and implementations so that the scope of the invention is not limited by the specific embodiments discussed herein.

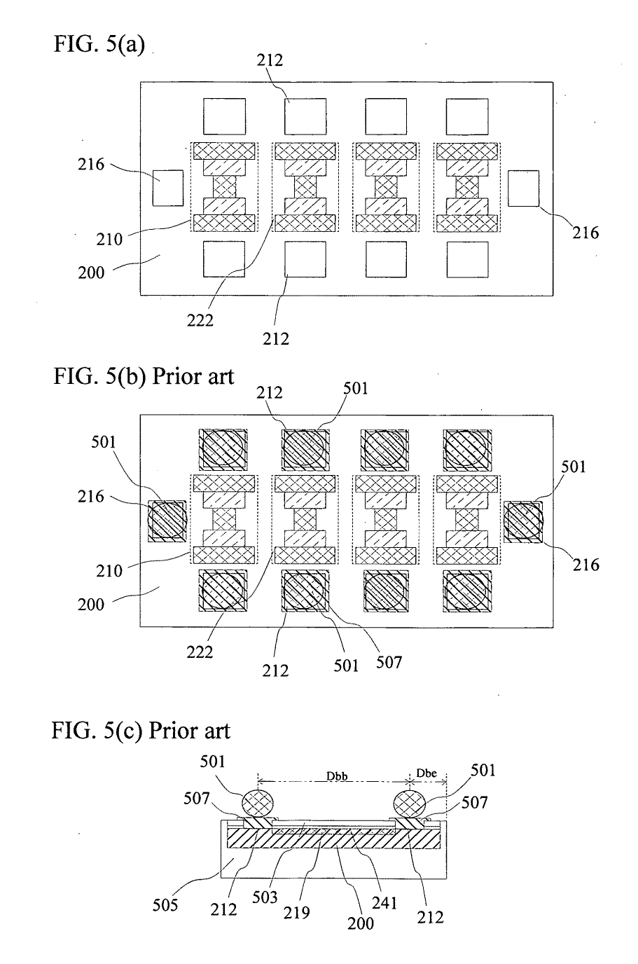

FIGS. 5(a-c) illustrate an example when conductor balls, instead of printed conductors are used to provide low impedance conductor leads. FIG. 5(a) shows the top view of a die (200) that is the same as the die in FIG. 2(c). After placing protection layers (503, 505) on the die (200), “under bump metallization” (UBM) layers (507) are placed on the pads (212, 216), and conductor balls (501) are placed on the UMB layers (507), as illustrated by the top view in FIG. 5(b) and the cross section view in FIG. 5(c). The technologies to place conductor balls have been developed for ball grid array (BGA) integrated circuit packages. The device illustrated in FIGS. 5(b, c) can support the same functions as the prior art device illustrated in FIGS. 2(d, e), but the costs of bumping technologies are typically significantly higher than printing technologies. The size of bumping chip is limited by the required ball-to-ball spacing (Dbb) and ball-to-edge spacing (Dbe). Present day bumping technologies typically require Dbb larger than 0.4 mm and Dbe larger than 0.08 mm. These requirements limit the capability to reduce sized of bumping chips. Using edge conductor leads instead of bumping removed those constraints. Therefore, chips of the present invention using edge conductor leads typically can achieve smaller sizes than prior art chips using bumping balls or bumping structures.

The costs of the electrical diode circuits discussed in the above examples are typically dominated by the costs of the single-crystal semiconductor devices. It is desirable to use electrical diodes manufactured on none-crystalline semiconductor for further cost reduction. Non-crystalline semiconductor materials, by definition, mean polycrystalline or amorphous semiconductor materials.

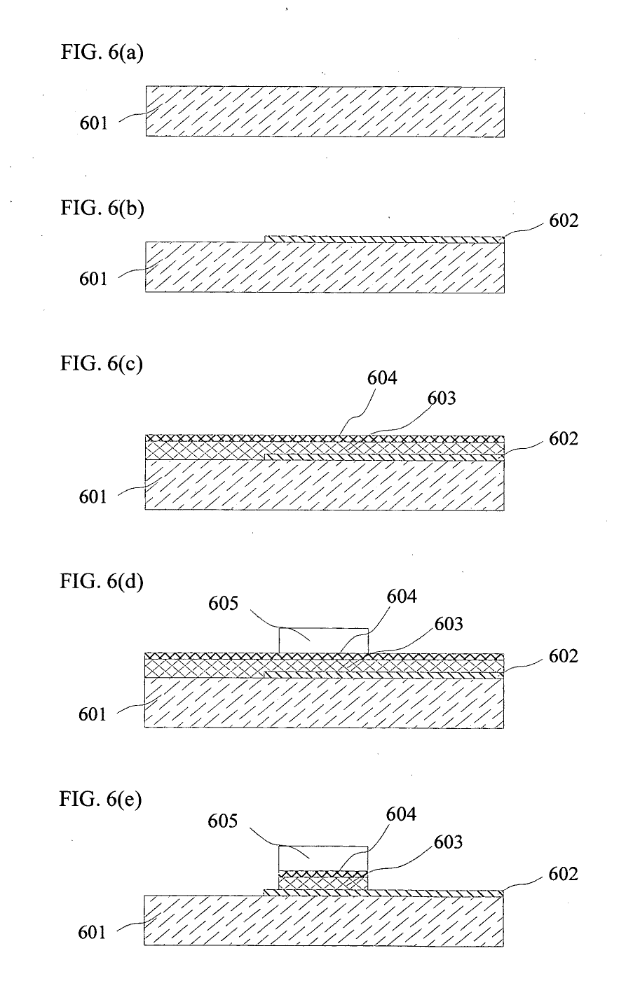

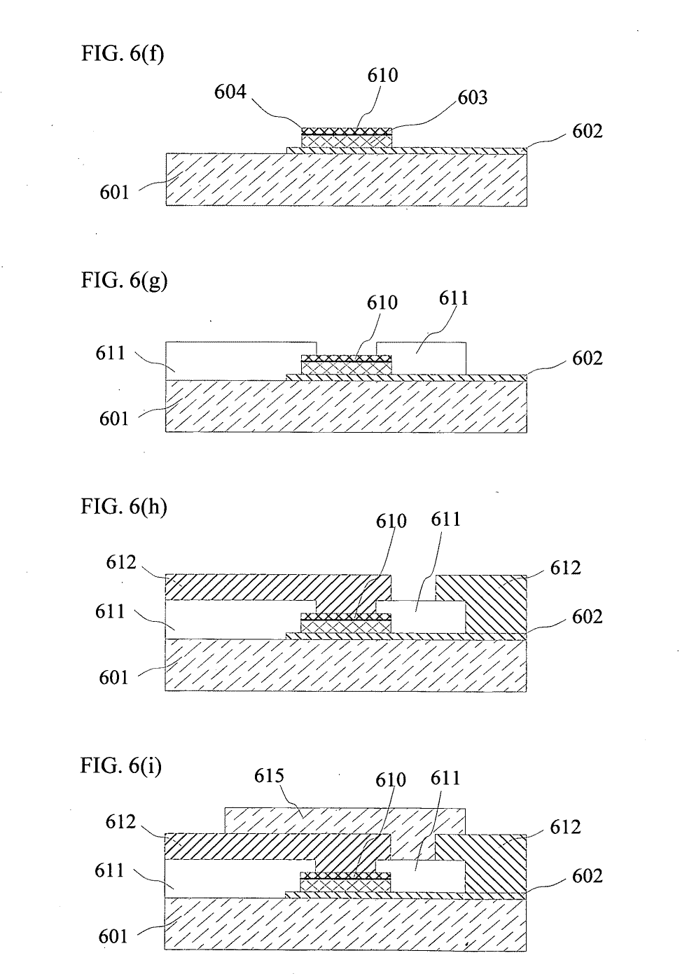

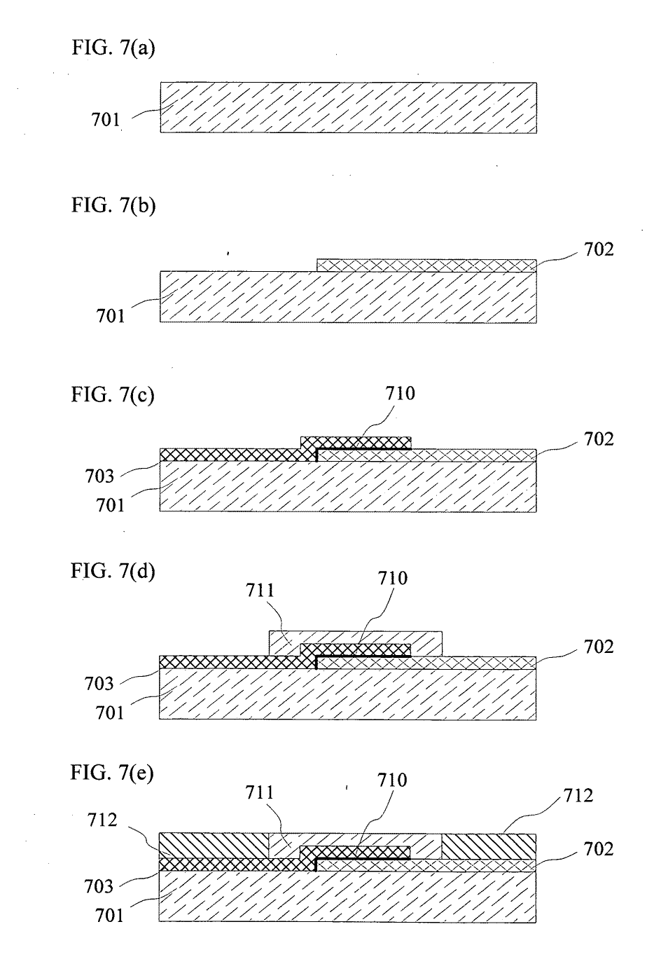

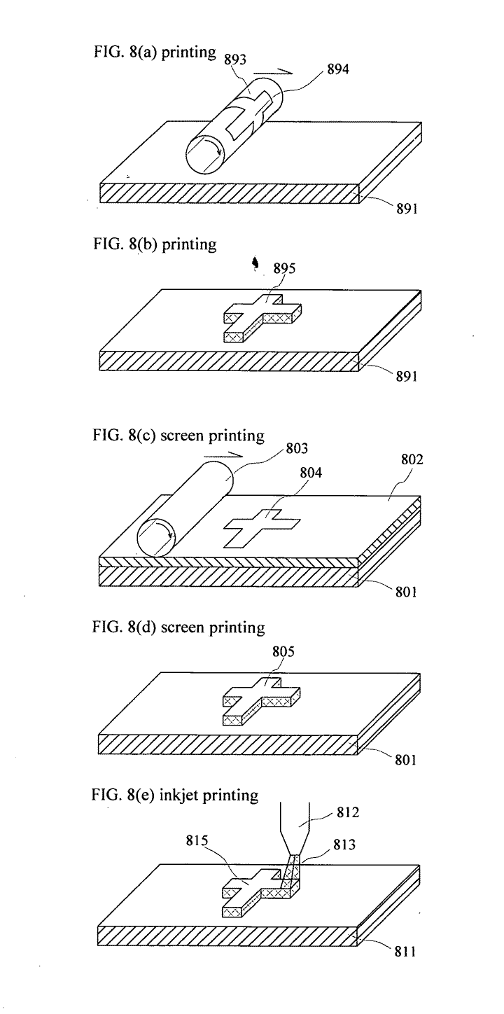

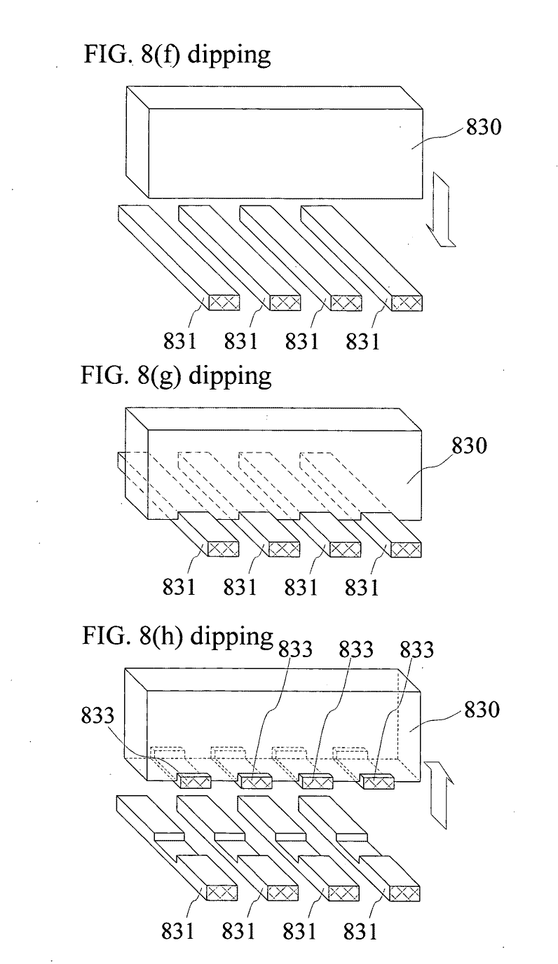

FIGS. 6(a-i) are cross-section diagrams illustrating exemplary manufacture steps for none-crystalline semiconductor electrical diodes. FIG. 6(a) shows the cross-section view of a substrate (601). This substrate can be ceramic, plastic, metal, semiconductor, or other types of materials. FIG. 6(b) shows the cross-section view when a conductor layer (602) is deposited on the substrate (601). FIG. 6(c) shows the cross-section view when two none-crystalline layers (603, 604) are deposited on top of the substrate to form electrical diodes. These two electrical diode layers (603, 604) can be a p-type non-crystalline semiconductor layer and an n-type non-crystalline semiconductor layer forming P-N junction electrical diodes. Another option is to deposit one non-crystalline semiconductor layer, then use surface doping methods to generate the second semiconductor layer of opposite doping type. Another option is to use one non-crystalline semiconductor layer (603) and one metal layer (604) to form Schottky diodes. Common examples of non-crystalline materials (603, 604) are polycrystalline silicon or amorphous silicon. FIG. 6(d) shows the cross-section view when a masking layer (605) is deposited on the electrical diode layers (602, 603). The pattern of this masking layer (605) can be defined by printing, photolithography, or other types of methods. The next step is to etch away electrical diode layers (603, 604) that are not under the masking layer (605), as illustrated in FIG. 6(e). After removing the masking layer (605), electrical diodes (610) are formed between the two electrical diode layers (603, 604) with patterns defined by the masking layer, as illustrated in FIG. 6(f). The next step is to print an insulator layer (611) with desired patterns, as illustrated in FIG. 6(g). Typical materials used as insulators for printed circuits are doped glasses. The next step is to print a conductor layer (612) to connect the electrical diode (610) and to form conductor leads, as illustrated in FIG. 6(h). A protective insulator layer (615) is printed to cover the electrical diode (610) as illustrated in FIG. 6(i). Epoxy resin is a typical material used for the protective insulator layer. An electrode layer can be printed to cover the exposed conductor layer as illustrated in previous examples. For simplicity, the above example only shows structures related to electrical diodes. Formation of other components such as resistors and capacitors are not shown in the above example. After electrical components have been printed, the substrate (601) can be sliced into individual chips in shapes similar to previous examples.

FIGS. 6(a-i) are simplified symbolic diagrams illustrating exemplary manufacture steps for non-crystalline electrical diodes. Device properties of non-crystalline electrical diodes, such as the breakdown voltage of breakdown diodes or reverse bias leakage current, are typically not as well controlled as those of single-crystal electrical diodes. However, many applications such as ESD protection do not require accurate control on many electrical diode properties. Electrical diodes formed on non-crystalline semiconductors are often sufficient to support ESD protection circuits. The ESD protection chip made by methods similar to those in FIGS. 6(a-i) can support the same functions as prior art ESD protection chips.

While specific embodiments of the invention have been illustrated and described herein, it is realized that other modifications and changes will occur to those skilled in the art. For example, in the above example the electrical diodes are patterned by masked processes, while printing technologies are also applicable to pattern the electrical diodes. The electrical diode layers can be two layers deposited separately, or one deposited layer followed by surface doping processes to create the second layer. It is to be understood that there are many other possible modifications and implementations so that the scope of the invention is not limited by the specific embodiments discussed herein.

FIGS. 7(a-e) are cross-section diagrams illustrating another set of exemplary manufacture steps for making none-crystalline semiconductor electrical diodes using printing technologies. FIG. 7(a) shows the cross-section view of a substrate (701). FIG. 7(b) shows the cross-section view when a non-crystalline semiconductor layer (702) is printed on the substrate (701). FIG. 7(c) shows the cross-section view when another non-crystalline layer (703) of different doping type is printed on the substrate. The second layer (703) partially overlaps with the first layer (702) to form junction electrical diodes (710) between the overlapped areas. These two layers (702, 703) can be a p-type non-crystalline semiconductor layer and an n-type non-crystalline semiconductor layer forming P-N junction electrical diodes, or one non-crystalline semiconductor layer and one metal layer forming Schottky diodes. Common examples of non-crystalline semiconductor materials are polycrystalline silicon or amorphous silicon. The two layers also can be two different semiconductors. FIG. 7(d) shows the cross-section view when a protective insulator layer (711) is printed to cover the electrical diode (710). FIG. 7(e) shows the cross-section view when a conductor layer (712) is printed to form conductor leads and/or connections to the electrical diode (710). Using similar manufacture processes, we also can integrate resistors, capacitors, or other circuit components to work with the non-crystalline electrical diodes (710). For simplicity, the above example did not illustrate structures for other components. After electrical components have been printed, the substrate (701) is sliced into individual chips. The ESD protection chips or electrical diode chips made by processes similar to those in FIGS. 7(a-e) can support the same functions as prior art ESD protection chips or electrical diode chips except that Integrated Circuit packages are replaced by printed conductor leads directly connected to the electrical diode(s) and that single crystal electrical diode(s) are replaced by printed non-crystalline electrical diode(s). The ESD protection chips or electrical diode chips with printed conductor leads typically can be smaller than 0402 or 0201 or 01005 resistor chips with equivalent I/O counts. It is desirable to make the dimensions of the ESD protection chips or electrical diode chips similar to the dimensions of 0402, 0201, 01005, or other types of resistor chips. It is also desirable to make the footprint of the ESD protection chip or electrical diode chips compatible to the footprints of 0402, or 0201, or 01005, or other types of resistor chips.

While specific embodiments of the invention have been illustrated and described herein, it is realized that other modifications and changes will occur to those skilled in the art. It is to be understood that there are many other possible modifications and implementations so that the scope of the invention is not limited by the specific embodiments discussed herein.

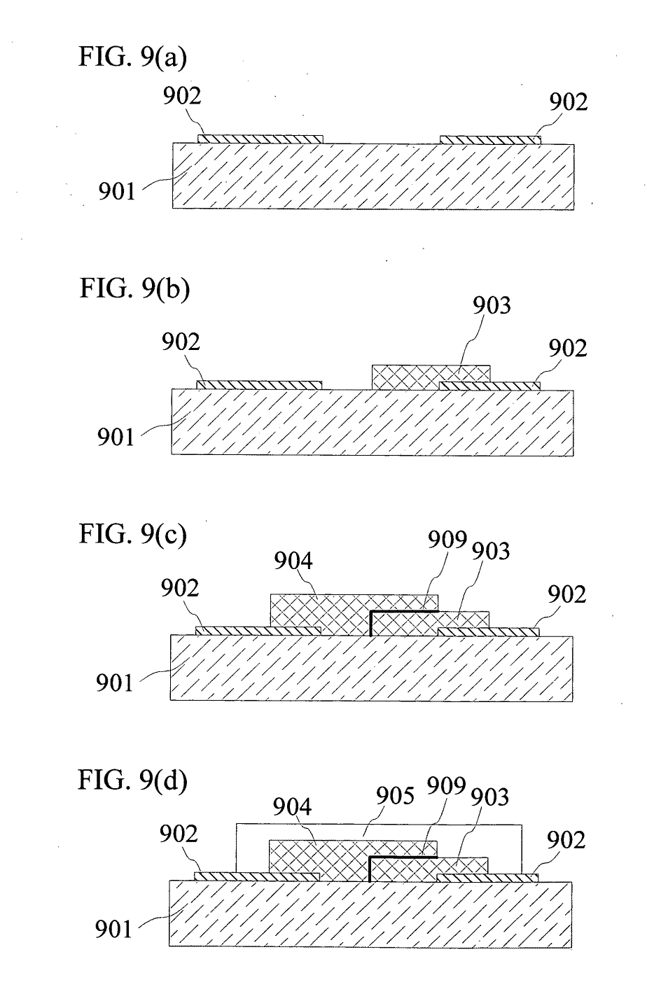

In the above examples, semiconductor electrical diodes are packaged into chips before they are placed on circuit boards. It is desirable to print semiconductor electrical diodes directly on printed circuit boards. FIG. 9(a) is a simplified symbolic cross-section diagram for a circuit board (901) that has surface conductor traces (902). Normally, electrical diode circuits are packaged into chips before they can be soldered on circuit boards. Printed non-crystalline electrical diodes can be printed directly onto circuit boards without packaging. FIG. 9(b) shows the cross-section view when a non-crystalline semiconductor layer (903) is printed on the circuit board (901). FIG. 9(c) shows the cross-section view when another non-crystalline layer (904) of different doping type is printed on the circuit board (901). The second layer (904) partially overlaps with the first layer (903) to form junction electrical diodes (909) between the overlapped areas. These two layers (903, 904) can be a p-type non-crystalline semiconductor layer and an n-type non-crystalline semiconductor layer forming P-N junction electrical diodes, or one non-crystalline semiconductor layer and one metal layer forming Schottky diodes. Common examples of non-crystalline semiconductor materials are polycrystalline silicon or amorphous silicon. The two layers also can be two different semiconductors. FIG. 9(d) shows the cross-section view when a protective insulator layer (905) is printed to cover the electrical diode (909). The circuit board (901) can be printed circuit boards (PCB), a flexible printed circuit board commonly used by mobile devices, glass circuit boards commonly used for optical display devices, the substrate of a BGA package, or other kinds of board level substrates.

While specific embodiments of the invention have been illustrated and described herein, it is realized that other modifications and changes will occur to those skilled in the art. It is therefore to be understood that the appended claims are intended to cover modifications and changes as fall within the true spirit and scope of the invention.

What is claimed is:

1. A surface mount package chip, comprising:
semiconductor electrical diode(s) disposed on a substrate;
edge conductor leads deposited on the surface(s) and extend to the edge(s) of the surface mount package chip to function as external electrical connections for the semiconductor electrical diode(s);
Wherein the edge conductor leads comprise dried-ink conductors disposed on the surface(s) of the surface mount chip and patterned by printing process(es).

2. The surface mount package chip of claim 1 wherein the surface mount package chip having an area substantially the same as or smaller than the area of standard 0402 surface mount resistor chips with equivalent I/O count.

3. The surface mount package chip of claim 1 wherein the surface mount package chip having an area substantially the same as or smaller than the area of standard 0201 surface mount resistor chips with equivalent I/O count.

4. The surface mount package chip of claim 1 wherein the surface mount package chip having an area substantially the same as or smaller than the area of standard 01005 surface mount resistor chips with equivalent I/O count.

5. The surface mount package chip of claim 1 wherein the semiconductor electrical diode(s) constituting external electrostatic discharge (ESD) protection circuits.

6. The surface mount package chip of claim 1 wherein the semiconductor electrical diode(s) is(are) manufactured on a single crystal semiconductor substrate.

7. The surface mount package chip of claim 1 wherein the semiconductor electrical diode(s) is(are) manufactured on a none-crystalline semiconductor.

8. The surface mount package chip of claim 1 wherein the semiconductor electrical diode(s) is(are) Schottky diode(s).

9. The surface mount package chip of claim 1 wherein the semiconductor electrical diode(s) is(are) breakdown diode(s).

10. The surface mount package chip of claim 1 further comprises electromagnetic interference (EMI) filter(s).

11. The surface mount package chip of claim 1 wherein the edge conductor leads comprise dried-ink conductors patterned by a screen printing process.

12. The chip of claim 1 wherein the edge conductor leads comprise dried-ink conductors patterned by a dipping process.

13. The surface mount package chip of claim 1 wherein the surface mount package chip has a compatible foot print with a standard surface mount resistor chip.

14. A method for manufacturing a surface mount package chip, comprising the steps of:
forming semiconductor electrical diode(s) on a substrate;
forming a plurality of edge conductor leads on the surface and extend to the edge(s) of the surface mount package chip to function as external electrical connections for the semiconductor electrical diode(s);
Wherein the step of forming a plurality of edge conductor leads comprises a step of printing conductors on the surface(s) of the surface mount chip.

15. The method in claim 14 comprises a step of configuring the surface mount package chip with an area substantially the same as or smaller than the area of standard 0401 surface mount resistor chips with equivalent I/O count.

16. The method in claim 14 comprises a step of configuring the surface mount package chip with an area substantially the same as or smaller than the area of standard 0201 surface mount resistor chips with equivalent I/O count.

17. The method in claim 14 comprises a step of configuring the surface mount package chip with an area substantially the same as or smaller than the area of standard 01005 surface mount resistor chips with equivalent I/O count.

18. The method in claim 14 further comprises a step of configuring the electrical diode(s) to function as an external electrostatic discharge (ESD) protection circuit.

19. The method in claim 14 wherein the step of manufacturing the semiconductor electrical diode comprises a step of manufacturing the electrical diode(s) on a single crystal semiconductor substrate.

20. The method in claim 14 wherein the step of forming the semiconductor electrical diodes further comprises a step of manufacturing the semiconductor electrical diodes as none-crystalline electrical diode(s).

21. The method in claim 14 wherein the step of manufacturing the semiconductor electrical diode comprises a step of forming Schottky diode(s) in the surface mount package chip.

22. The method in claim 14 wherein the step of manufacturing the semiconductor electrical diode comprises a step of forming breakdown diode(s) in the surface mount package chip.

23. The method in claim 14 further comprises a step of integrating an electromagnetic interference (EMI) filter into the surface mount package chip.

24. The method in claim 14 wherein the step of printing the edge conductor leads further comprises a step of screen printing the edge conductor leads on the edge(s) of the soldering surface of the surface mount package chip.

25. The method in claim 14 wherein the step of printing the edge conductor leads further comprises a step of dipping and patterning the edge conductor leads.

26. The method in claim 14 comprises a step of forming the surface mount package chip with a footprint compatible with standard surface mount resistor chips.
